(19) United States
(12) Patent Application Publication
(10) Pub. No.: US 2009/0001491 A1
(43) Pub. Date: Jan. 1, 2009

(54) Method for producing a microchip that is able to detect infrared light with a semiconductor at room temperature

(75) Inventors: Meir Israelowitz, Toronto (CA); Herbert Peter von Schroeder, Toronto (CA); Chris Holm, Wuppertal (DE); Christoph Gille, Berlin (DE); Syed Rizvi, Lake Mary, FL (US)

Correspondence Address: Herbert P Von Schroeder, 191 Ellis Avenue, Toronto, ON, CA

(73) Assignee: BIOMIMETICS TECHNOLOGIES INC, Toronto (CA)

(21) Appl. No.: 11/895,800

(22) Filed: Aug. 28, 2007

Related U.S. Application Data
(60) Provisional application No. 60/855,162, filed on Oct. 30, 2006.

(51) Int. Cl. H01L 31/00; H01L 21/00

(52) U.S. Cl. 257/432; 438/69; 257/E31.001; 257/E21.001

(57) ABSTRACT

The inventions relate to a method for producing a microchip that is able to detect infrared light with a semiconductor, the basic infrared light is absorber by the semiconductor surrounded, attached or embedded in a polymer which is brought in a thin layer on the surface of the semiconductor and which is grown by polymer around the semiconductor in an acid fluid.

### RELATED APPLICATION INFORMATION

This application claims priority to U.S. Patent Application No. 60/855,162, filed August, 2006, which is hereby incorporated by references in its entirety.

### BACKGROUND OF THE INVENTION

Most high performing infrared (IR) imaging systems are based on solid state semiconductors and require complicated cooling systems. Uncoiling MEMS-based IR sensors, commonly referred to as microbolometers have emerged. Although they are not semiconductor based, they still employ doped semiconductors as their sensing material. These devices remain useful for commercialization, but suffer from high noise and the need for exotic materials.

There are examples in nature, including specific species of snakes, beetles and bacteria that possess IR sensors. These natural sensors rely on proteins or peptides and always work at room temperature. However, a drawback to mimicking natural systems that incorporate proteins is that they require a biological system to prevent denaturation or degradation of the proteins.

Consider the Melanophila acuminata beetle which can detect fires from distances of 50 Km via specific sensors that are uncooled. The structure of the sensors has been described by Israelwoitz, et al (Israelowitz M, Rizvi S W H and von Schroeder H P, 2007. Fluorescence of the “fire-chaser” beetle Melanophila acuminata, 126, 149-154) and others. To resolve the problems of inorganic IR models that require extensive cooling systems and organic systems that rely on proteins, this application presents an inorganic model that mimics an organic model.

It is known in the art that transferring IR of sun light into electrical current has practical applications, however harnessing IR energy is presently not practical by existing methods. The device of this application has the ability to harness IR energy and convert it into an electrical impulse or signal.

It is also known in the art that different types of cancer cells produce warmth and an IR signature. The warmth given by the cells is small and very difficult to measure or detect using available IR detectors. The device of this application has the ability to detect IR signal for use as an IR camera.

Typical metal attachment to polymers patents as follow United States of America patents:

| | |
|---|---|
| 3259559 | Schnedle |
| 353730 | Arsac |
| 3261711 | Sallo |
| 3499881 | Poppe |
| 3516848 | Foulke |
| 3607350 | Rathsack |
| 3666552 | Ayukawa |
| 3682786 | Brown |
| 3684554 | Donald |
| 4,882,292 | Sudholter, et al |
| 5,140,393 | Hijihigawa, et al |
| 5,331,310 | Stetter, et al |
| 5,585,457 | Newkomem, et al |
| 6,024,924 | Schoning, et al |
| 6,312,809 | Crooks, el al |
| 6,312,809 | Newkome, et al |
| 6,410,680 | Kubota, et al |
| 6,664,315 | Tomalia, et al |
| 6,794,327 | Youngs, et al |
| 6,812,298 | Dvornic, et al |
| 6,881,490 | Kambe, et al |
| 6,897,266 | Kenig-Dodiuk, et al |
| 60,845,162 | Israelowitz, et al |

### REFERENCES

All the publications and patents mention herein, are hereby incorporated by reference in their entirely as if each individual publication or patent was specifically and individually indicated to be incorporated by reference. In case of conflict, the present application, including any definition herein, will control.

### EQUIVALENTS

While the specific embodiments have been discussed, the above specification is illustrative and not restrictive. Many variations will become apparent to those skilled in the art upon review of this specification. The full scope of the disclosure should be determined by reference of the claims, along with their full scope of equivalents, and specifications, along such variations.

### SUMMARY OF THE INVENTION

The invention consists of a method for producing a microchip that is able to detect infrared light with a basic infrared light absorber surrounded by the semiconductor and attached and/or embedded by a polymer which is brought in a thin layer on the surface of the semiconductor and which is grown around the semiconductor.

One advantage is that this microchip functions at room temperature and does not require a cooling system.

A second advantage, particularly since there is no need for any special cooling systems, is that the microchip can be integrated into any optical system, detection system and/or integrated into optical switches, electrical switches, sensor systems and light energy conversion.

The third advantage is it is able to recognize the different IR signatures given by different organic or inorganic materials, and as such can be used to identify specific material, tissues and cells.

A final advantage is that the microchip can be manufactured using current technologies including soft lithography, stamp printing, ink-jet printing and off set printing.

### EXAMPLES

For example taking one of the semiconductors,
VI semiconductors
   Cadmium selenide (CdSe)
   Cadmium sulfide (CdSs)
   Cadmium telluride (CdTe)
   Zinc oxide (ZnO)
   Zinc selenide (ZnSe)
   Zinc sulfide (ZnS)
   Zinc telluride (ZnTe)
II-VI ternary alloy semiconductors
   Cadmium zinc telluride (CdZnTe, CZT)
   Mercury cadmium telluride (HgCdTe)
   Mercury zinc telluride (HgZnTe)
   Mercury zinc selenide (HgZnSe)
I-VII semiconductors
   Cuprous chloride (CuCl)
IV-VI semiconductors
   Lead selenide (PbSe)
   Lead sulfide (PbS)
   Lead telluride (PbTe)
   Tin sulfide (SnS)
   Tin telluride (SnTe)
IV-VI ternary semiconductors
   Lead tin telluride (PbSnTe)
   Thallium tin telluride (TL₂SnTe₅)
   Thallium germanium telluride (Tl₂GeTe₅)
V-VI semiconductors
   Bismuth telluride (Bi₂Te₃)
   II-V semiconductors
   Cadmium phosphide (Cd₃P₂)
II-V semiconductors
   Cadmium phosphide (Cd₃P₂)
   Cadmium arsenide (Cd₃As₂)
   Cadmium antimonide (Cd₃Sb₂)
   Zinc phosphide (Zn₃P₂)
   Zinc arsenide (Zn₃As₂)
   Zinc antimonide (Zn₃Sb₂)

For example taken one of the polymers,
Dendrimers
Poly-acethylene
Fullerenes
Melamine
poly(amidoamine) (PAMAMOS)
non-polar polymers
Fluoropolymers
Flurocarbons
Polytetrafluoroethylene

For example depositing the crystal (ionic charges) in the polymer with acid fluid,
Carboxylate sodium salt
Sodium borohydride
Hydrogen sulfide

For example bringing one drop or a thin layer on the surface of the semiconductor and letting it grow it in the acid fluid until we bring electrons to the edge of the semiconductor. The measured current is the power of infrared radiation given by the cancer.

The microchip is given information of the cancer, type and dimensions of the cancer with the direction where the cancer is located.

For the growing of the layer we increase the temperature at 200° C./392° F.

### PREFERRED EMBODIMENT OF THE INVENTION SHOWN IN THE FIGURES

The figures show only the atomic configuration of the polymer layer on the semiconductor.

FIG. 1 embodiment of the present invention system is showing two overlapping face-centered-cubic lattices and semiconductor is Culn Se₂ unit cell (where Se is selenide, Cu is cooper and In is indium or Ga is gallium).

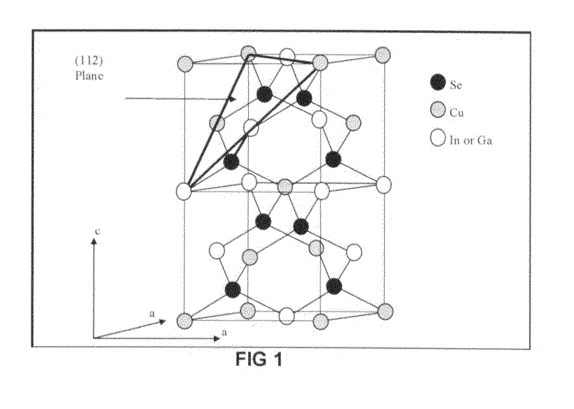

FIG. 2 embodiment of the present invention system showing infrared photons (1) and the poly(amidoamine) (PAMAMO) 4 Generation (2) with a semiconductor attached (3), releasing a electron (4).

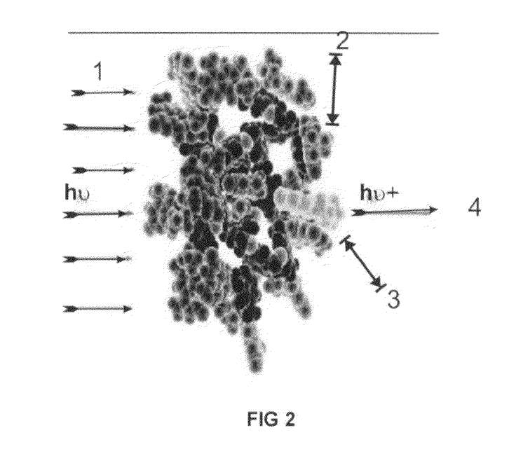

FIG. 3 embodiment of the present invention system is shown atoms of the polymers (1) surrounded by atoms of the semiconductor (2).

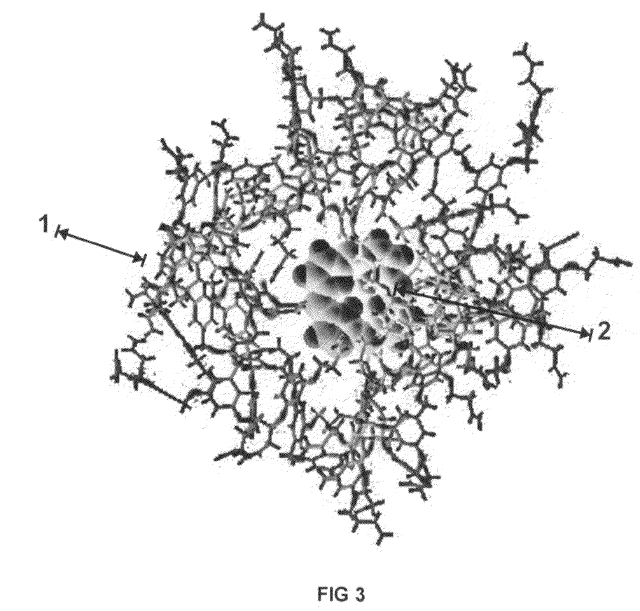

FIG. 4 embodiment of the present invention system showing a group polymers (1) and the empty part between or space is filled by the atoms of the heat sync (2). The polymer is surrounding the top of the semiconductor (3).

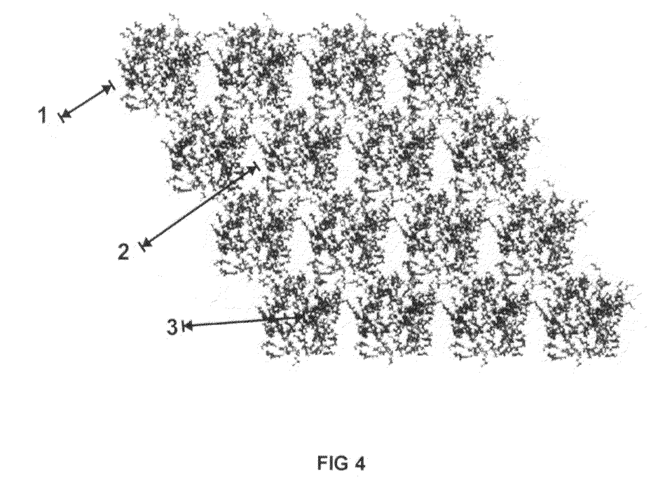

FIG. 5 embodiment of the present invention system is showing the case of the single case (1) and electros connected to the chip cell (2). The coating with polymer and semiconductor (3) is surrounding by the heat sync (4).

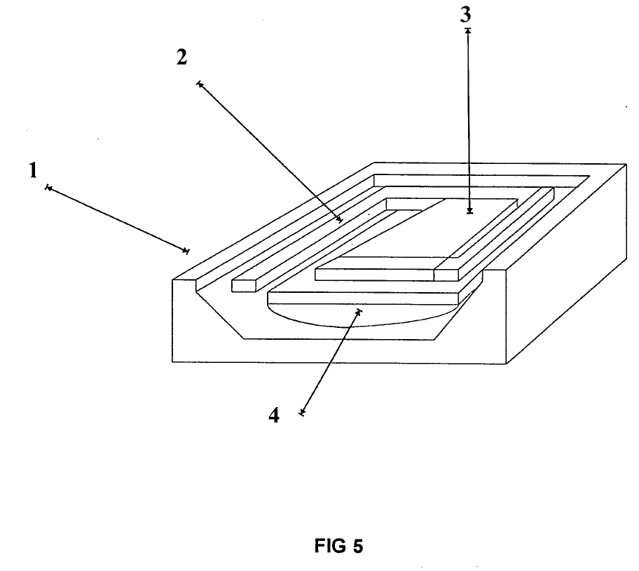

FIG. 6 embodiment of the present invention system is showing electros (1) with the polymer layer and the semiconductor (2). The microchip is protected by heat sync (3)

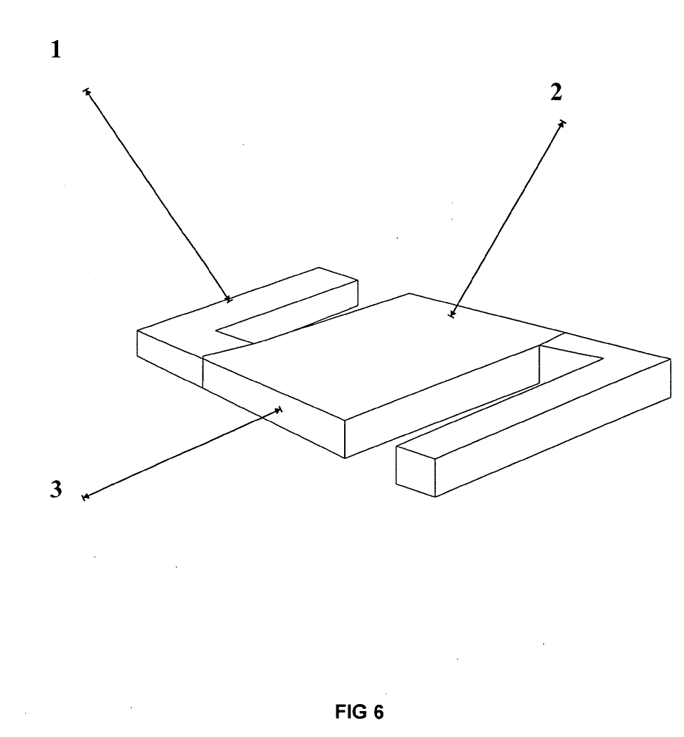

FIG. 7 embodiment of the present invention system is showing a single cell of the microchip (1) and circuit given by electrons (2) including the heat sync.

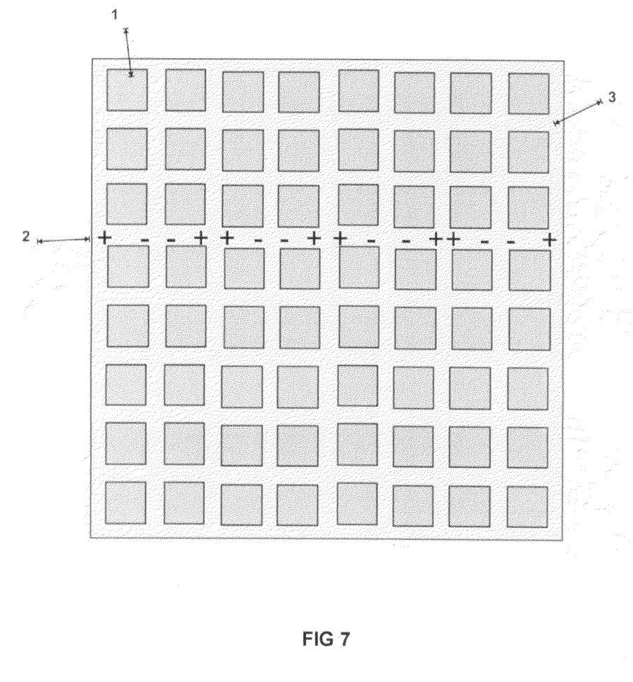

FIG. 8 present invention system showing the microchip system with sensor, amplifier, low pass filter and output measure.

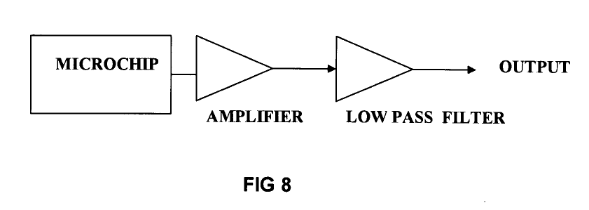

1. Method for producing a microchip that is able to detect infrared light with a semiconductor, the basic infrared light is absorber by the semiconductor surrounded by a polymer which is brought in a thin layer on the surface of the semiconductor and which is grown by polymer around the semiconductor in an acid fluid.

2. Method for producing a microchip that is able to detect infrared light with a semiconductor, the basic infrared light absorber by the semiconductor connected by a polymer which is brought in a thin layer on the surface of the in an acid fluid semiconductor and which is grow/attached around the semiconductor in an acid fluid.

3. Method for producing a microchip which is able to detect infrared light with a semiconductor, the basic infrared light absorber by the semiconductor attached/embedded by a polymer which is brought in a thin layer on the surface of the in an acid fluid semiconductor and which is grown/embedded around the semiconductor in an acid fluid.

4. Method according claim 1, claim 2 and claim 3 the semiconductor is chosen from the does semiconductors, which are able to absorbent infrared light and to conduct electrons.

5. Method according claim 1 claim 2 and claim 3 to take semiconductor made atoms from group VI or/and group II.

6. Method according claim 5 to take semiconductor made atoms from group VI semiconductors
Cadmium selenide (CdSe)
Cadmium sulfide (CdSs)
Cadmium telluride (CdTe)
Zinc oxide (ZnO)
Zinc selenide (ZnSe)
Zinc sulfide (ZnS)
Zinc telluride (ZnTe)
II-VI ternary alloy semiconductors
Cadmium zinc telluride (CdZnTe, CZT)
Mercury cadmium telluride (HgCdTe)
Mercury zinc telluride (HgZnTe)
Mercury zinc selenide (HgZnSe)
I-VII semiconductors
Cuprous chloride (CuCl)
IV-VI semiconductors
Lead selenide (PbSe)
Lead sulfide (PbS)
Lead telluride (PbTe)
Tin sulfide (SnS)
Tin telluride (SnTe)
IV-VI ternary semiconductors
Lead tin telluride (PbSnTe)
Thallium tin telluride (TL₂SnTe₅)
Thallium germanium telluride (Tl₂GeTe₅)
V-VI semiconductors
Bismuth telluride (Bi₂Te₃)
II-V semiconductors
Cadmium phosphide (Cd₃P₂)
II-V semiconductors
Cadmium phosphide (Cd₃P₂)
Cadmium arsenide (Cd₃As₂)
Cadmium antimonide (Cd₃Sb₂)
Zinc phosphide (Zn₃P₂)
Zinc arsenide (Zn₃As₂)
Zinc antimonide (Zn₃Sb₂)

7. Method according claim 1, claim 2 and claim 3 taking a polymer which is a good conductor of electrons, like dendrimers and nanocarbon tube.

8. Method according claim 1, claim 2 and claim 3 taking a polymer which is a good conductor of electrons where one of the polymers,
Poly-acethylene
Fullerenes
Melamine
poly(amidoamine) (PAMAMOS)
non-polar polymers
Fluoropolymers
Flurocarbons
Polytetrafluoroethylene

9. Method according claim 1, claim 2 and claim 3 taking deposit semiconductor into polymer where the semiconductor and polymer is growing,
Sodium borohydride
Carboxylate sodium salt
Hydrogen sulfide

10. Method according claim 1 taken temperature from 200° C./392° F. and 380° C./716° F. especially in the range 250° C./482° F. to 300° C./572° F.

11. Microchip which is able to detect infrared light with a semiconductor as the basic infrared light absorber and surrounded by a polymer which is brought in a thin layer on the surface of the semiconductor.

12. Microchip which is able to detect infrared light with a semiconductor as the basic infrared light absorber and attached to the polymer which is brought in a thin layer on the surface of the semiconductor.

13. Microchip which is able to detect infrared light with a semiconductor as the basic infrared light absorber and attached to the polymer which is brought in a thin layer on the surface of the semiconductor.

14. Microchip which is able to detect infrared light with a semiconductor as the basic infrared light absorber and embedded in the polymer which is grown around the semiconductor.

15. Method according claim 1, claim 2 and claim 3 a layer, with a polymer layer and heat sync layer surrounding and protecting the semiconductor against heat production.

16. Method according claim 1, claim 2 and claim 3 a layer, with a polymer layer and heat sync layer attached and protecting the semiconductor against heat production.

17. Method according claim 1, claim 2 and claim 3 a layer, with a polymer layer and heat sync layer embedded and protecting the semiconductor against heat production.

18. Method according claim 1 and claim 2 and claim 3 of several layers, with a polymer layers and heat sync layers surrounding and protecting the semiconductor against heat production.

19. Method according claim 1 and claim 2 and claim 3 of several layers, with a polymer layers and heat sync layers attached and protecting the semiconductor against heat production.

20. Method according claim 1 and claim 2 and claim 3 of several layers, with a polymer layers and heat sync layers embedded and protecting the semiconductor against heat production.

21. Method according claim 1, claim 2 and claim 3 with connections between semiconductor and the polymer.

22. Method according claim 1, claim 2 and claim 3 attached between semiconductor and the polymer.

23. Method according claim 1, claim 2 and claim 3 with embedded between semiconductor and the polymer.

24. Microchip which is able to detect infrared light with a semiconductor, surrounded by a polymer which is brought in a thin layer on the surface of the semiconductor and which is grown around the semiconductor

25. Microchip according claim 7 with heat sync embedded in the polymer protecting the semiconductor.

26. Microchip according claim 7 with heat sync attached in the polymer protecting the semiconductor.

27. Microchip according claim 7 and claim 8 buildups in a layer, with a polymer layer and a heat sync layer surrounding and protecting the semiconductor with connections between semiconductor and the polymer.

28. Microchip according claim 7 and claim 8 buildups in a layer, with a polymer layer and a heat sync layer embedded and protecting the semiconductor with connections between semiconductor and the polymer.

29. Microchip according claim 7 and claim 8 buildups in several layers, with a polymer layer and a heat sync layers surrounding and protecting the semiconductor with connections between semiconductor and the polymer.

30. Microchip according claims 1 with a minimum of quantum holes, by the polymer intertwine creating a network and the polymer.

31. Microchip according claim 11 is between two electrical plates or the polymer layer with the semiconductor connected to electrode to complete a circuit.

32. Microchip according claim 11 is between two electrical plates or the polymer layer with the semiconductor connected to electrode to complete a transistor.

33. Microchip according claim 11 is between two electrical plates or the polymer layer with the semiconductor connected to electrode to form a sensor.

34. Microchip according claim 11 is between two electrical plates or the polymer layer with the semiconductor connected to electrode for light energy conversion.

35. Microchip according claim 11 is between two electrical plates or the polymer layer with the semiconductor connected to electrode to be differencing the warm of inorganic.

36. Microchip according claim 11 is between two electrical plates or the polymer layer with the semiconductor connected to electrode to be differencing the warm of organic.

37. Microchip according claim 11 is between two electrical plates or the polymer layer with the semiconductor connected to electrode to optical system.

38. Microchip according claim 11 is between two electrical plates or the polymer layer with the semiconductor connected to electrode to a multiple array.

39. Microchip according claim 11 is between two electrical plates or the polymer layer with the semiconductor connected to electrode to a night optical system.

40. Microchip according claim 11 is between two electrical plates or the polymer layer with the semiconductor connected to electrode of machine vision.

41. Microchip according claim 11 is between two electrical plates or the polymer layer with the semiconductor connected to electrode to differencing the intensity differencing tissue.

42. Microchip according claim 11 is between two electrical plates or the polymer layer with the semiconductor connected to electrode to detect fire.
